(19) United States
(12) Patent Application Publication
(10) Pub. No.: US 2005/0000450 A1
(43) Pub. Date: Jan. 6, 2005

(54) Treatment subject elevating mechanism, and treating device using the same

(76) Inventor: Hachishiro Iizuka, Yamanashi-Ken (JP)

Correspondence Address: Smith Gambrell & Russell, Suite 800, 1850 M Street NW, Washington, DC, 20036, US

(21) Appl. No.: 10/492,979

(22) PCT Filed: Oct. 15, 2002
(86) PCT No.: PCT/JP02/10682

(30) Foreign Application Priority Data
Oct. 16, 2001 (JP) 2001-318636

(51) Int. Cl. C23C 16/00

(52) U.S. Cl. 118/728

(57) ABSTRACT

A lift mechanism for an object-to-be-processed is provided which can minimize displacement of an object-to-be-processed by quickly discharging the gas in the space on the side of the backside surface of the object-to-be-processed when the object-to-be-processed is mounted on a mount stand.

In a lift mechanism, in which a plurality of pin-insertion holes 50 are formed in a mount stand 38 provided inside a evacuatable processing container 22, a push-up pin 52 is inserted in each of said pin-insertion holes 50, said push-up pin 52 capable of moving upwardly and downwardly, and a push-up member moves said push-up pin upwardly and downwardly so as to mount an object-to-be-processed W on said mount stand, a communication path 66 is formed in said push-up pin to communicate the space S1 above said mount stand with the space S2 below said mount stand. The gas in the space on the side of the backside surface of an object-to-be-processed can thus be discharged quickly when the object-to-be-processed is mounted on the mount stand, thus inhibiting the object-to-be-processed to be displaced.

### TECHNICAL FIELD

The present invention relates to a lift mechanism for an object-to-be-processed such as a semiconductor wafer and to a processing apparatus using the same.

### BACKGROUND TECHNOLOGY

In the production of semiconductor integrated circuits, generally, an object-to-be-processed such as a semiconductor wafer proceeds through various single-wafer processes repeatedly, such as film formation, etching, heat treatment, modification and crystallization, to form an integrated circuit as intended. The processing of every kind as cited above is performed by introducing each processing gas required into a processing container, depending on the kind of processing: for example, a film deposition gas for film formation, ozone gas or the like for modification and inactive gas such as N₂ gas or O₂ gas for crystallization.

Taking as an example a single wafer processing apparatus that performs heat treatment on semiconductor wafers one by one, a mount stand incorporating a resistance heater for example is installed inside an evacuatable processing container, and a specific processing gas is provided on the upper surface of the mount stand on which a semiconductor wafer is mounted, and then all sorts of heat treatment are performed on the wafer under specific processing conditions.

Meanwhile the mount stand is provided with push-up pins, as publicly known, which can vertically rise and sink so that a wafer loaded into a processing container can be transferred onto the mount stand (as disclosed for example in the official gazette of Japanese Patent Application Publication No. 6-318630/1994). By moving these push-up pins upwardly and downwardly, a wafer can be mounted on the mount stand or otherwise a wafer mounted on the mount stand can be pushed off in the upper direction.

Details in this regard will hereinafter be explained with reference to FIGS. 18A and 18B.

FIGS. 18A and 18B are block diagrams illustrating a conventional lift mechanism for an object-to-be-processed which is provided in a mount stand of a processing apparatus. As shown in FIGS. 18A and 18B, a mount stand 2 has plurality of pin-insertion holes 4 e.g. three holes (only two of them are exemplified in the figure) formed therethrough, and push-up pins 6 are inserted respectively through the pin-insertion holes 4 in loose fit allowing upward-and-downward movement.

Each of the push-up pins 6 is supported at its lower end by a disengageable ring-shaped push-up member 8 which can move upwardly and downwardly by an actuator, not shown. Each of the push-up pins 6 is supported also by a collar portion 10 having an enlarged diameter provided on the upper end of the push-up pin 6, and this collar portion 10 fits into a recess 12 formed on the upper surface of the mount stand 2 as shown in FIG. 18B.

In transfer of a wafer W onto the mount stand 2, the push-up pins 6 are raised above as shown in FIG. 18A, and the upper ends of the push-up pins 6 support a wafer W on receipt from a transfer arm, not shown. Then, the push-up pins 6 move downwardly to completely sink into the pin-insertion holes 4 as shown in FIG. 18B, whereby the wafer W can be supported on the mount stand 2. The unloading operation of a wafer W from inside a processing container is just the reverse of the above operations.

At this point in which a wafer W is moved down and mounted on the mount stand 2 as shown sequentially in FIGS. 18A and 18B, there would be no problem if a gas existing in a space on the side of the backside surface of the wafer W, i.e. a space S1 between the backside surface of the wafer W and the upper surface of the mount stand 2, quickly escapes outwardly from the periphery of the wafer W, or quickly escapes to a space S2 on the backside surface of the mount stand 2 through the pin-insertion holes 4, as shown by an arrow 12 in FIG. 18B.

However, there has been a problem in a case that an escape speed of the gas in the space S1 decreases due to, for example, unnecessary film adhered on the inner walls of the pin-insertion holes 4 as processing of a wafer W proceeds or due to a wafer W of larger size. In this case, the wafer W floats in the air, though only a moment, because of the air-cushion effect of the gas pressure in the space S1, at which moment the wafer can sideslip out of alignment.

One of the possible solutions to this problem is to have the pin-insertion holes 4 with much larger diameter than the external diameter of the respective push-up pins 6 to leave larger gap therebetween, thereby speeding gas exhaust from the space S1. However, this approach cannot be adopted, given that the inclination angle of the push-up pins 6 relative to vertical would significantly increase and consequently a wafer W would be horizontally out of alignment beyond the permissible limit when the inclining push-up pins 6 are moved upwardly and downwardly.

### DISCLOSURE OF THE INVENTION

The purpose of the present invention is to provide a lift mechanism for an object-to-be-processed and a processing apparatus using the same, said lift mechanism capable of minimizing displacement of an object-to-be-processed by quickly discharging the gas in the space on the side of the backside surface of the object-to-be-processed when the object-to-be-processed is mounted on a mount stand.

The present invention is a lift mechanism for an object-to-be-processed including a plurality of pin-insertion holes formed in the mount stand provided inside an evacuatable processing container and a push-up pin inserted through each of said pin-insertion holes, said push-up pin capable of moving upwardly and downwardly, wherein a push-up member moves said push-up pin upwardly and downwardly so as to mount an object-to-be-processed on said mount stand, the lift mechanism characterized in that said push-up pin is structured to have a communication path formed therein so as to communicate the spaces above and below said mount stand.

Consequently, when an object-to-be-processed is mounted on the mount stand, the gas in the space on the side of the backside surface of the object-to-be-processed can be quickly discharged toward the space on the side of the backside surface of the mount stand through the communication path formed in the push-up pin, and thus an air-cushion effect is hardly created, and as a result the object-to-be-processed can be prevented from causing displacement, without sideslipping on the mount stand.

In this case, said push-up pin can be formed to comprise:
a pin body; and
a collar portion provided on the end portion of said pin body, said collar portion being held by the peripheral portion of an opening in the upper end of said pin-insertion hole when said push-up pin is moved downwardly.

Also, an upper opening of said communication path can be formed to open upwardly at the upper-end portion of said pin body.

Further, an upper opening of said communication path can be formed to open laterally at the upper-end portion of said pin body.

In this manner, the gas in the space on the side of the backside surface of an object-to-be-processed can be quickly and assuredly discharged because the upper opening of the push-up pin is open laterally and is prevented from being blocked by the side of the backside surface of the object-to-be-processed.

Furthermore, said collar portion can be formed into a shape of an upwardly-convex curved surface.

In this case, a channel can be formed in said collar portion in order to form a part of said opening.

In this manner by forming the channel in the collar portion of the push-up pin to form a part of the opening, this opening is prevented from being blocked by the side of the backside surface of an object-to-be-processed assuredly, and thus the gas in the space on the side of the backside surface of the object-to-be-processed can be discharged more assuredly.

Moreover, the lower end of said pin body can be held in a detachably mounted state on said push-up member. Alternatively, the lower end of said push-up pin can be held in a fixed state on said push-up member.

Moreover, a lower opening of said communication path can be formed to open laterally at the lower-end portion of said push-up pin.

In this manner by opening the lower opening of the push-up pin laterally, the opening can be prevented from being blocked by the push-up member assuredly.

A lift mechanism for an object-to-be-processed according to the present invention including a plurality of pin-insertion holes formed in the mount stand provided inside an evacuatable processing container and a push-up pin inserted through each of said pin-insertion holes, said push-up pin capable of moving upwardly and downwardly, wherein said push-up pin moves upwardly and downwardly so as to mount an object-to-be-processed on said mount stand, the lift mechanism is characterized in that:
a communication path is formed in said push-up pin so as to communicate the spaces above and below said mount stand;
a positioning drive pin is formed which is slidably inserted into said communication path of said push-up pin so as to position said push-up pin and to drive said push-up pin upwardly and downwardly; and
a push-up member can move said positioning drive pin upwardly and downwardly.

Said push-up pin may have a cylindrical pin body, and the upper-end portion of said pin body may be provided with an annular portion or a collar portion which is held on the peripheral portion of said pin-insertion hole when said push-up pin moves down.

The upper portion of said annular portion or said collar portion may be formed into a shape of a convex curved surface.

In this case that the upper portion of said annular portion or said collar portion is formed into a shape of a convex curved surface, displacement caused by inclination of the push-up pin is reduced due to the reduced contact area that supports an object-to-be-processed.

An upper opening of said communication path may be open upwardly or laterally at the upper end of said pin body.

In the case that the upper opening of the communication path is open laterally, the upper opening of the communication path is not blocked by the side of the backside surface of an object-to-be-processed, and thus the gas in the space on the side of the backside surface of the object-to-be-processed can be more quickly and assuredly discharged.

Said positioning drive pin can also be formed to have a projection or collar to engage the lower-end portion of said push-up pin when said positioning drive pin is raised.

Said communication path of said push-up pin can also be formed to have a projection, reduced-diameter portion or shoulder portion to engage the upper end of said positioning drive pin when said positioning drive pin is raised.

According to the present invention, when the positioning drive pin is raised, the projection or collar of the positioning drive pin engages the lower-end portion of the push-up pin, or the upper end of the positioning drive pin engages the projection, reduced-diameter portion or shoulder portion inside the communication path of the push-up pin, thereby moving the push-up pin upwardly.

The upper-end portion of said positioning drive pin can have an evaginated portion;
the lower-end portion of said communication path of said push-up pin can have a narrowed portion; and
the length of the maximum outside diameter of said evaginated portion can be longer than the length of the minimum inside diameter of said narrowed portion of said communication path.

According to the present invention, when the positioning drive pin moves downwardly, the evaginated portion of the positioning drive pin engages the narrowed portion of the communication path of the push-up pin, thereby assuredly moving the push-up pin downwardly.

The lower-end portion of said pin-insertion hole of said mount stand can be formed to have a projection which engages the lower end of said push-up pin when said push-up pin moves downwardly.

In this manner, the projection of the pin-insertion hole engages the push-up pin when the push-up pin moves downwardly, thereby supporting the push-up pin.

Said push-up member can be formed to slidably bear thereon the lower end of said positioning drive pin. The lower end of said positioning drive pin can be supported in a fixed state by said push-up member.

A processing apparatus according to the present invention is characterized by comprising:
an evacuatable processing container;
a mount stand to mount an object-to-be-processed; and any one of the lift mechanism for an object-to-be-processed described above.

### BRIEF DESCRIPTION OF THE DRAWINGS

FIG. 1 is a cross-sectional block diagram showing a processing apparatus according to the present invention.

FIG. 2 is a plane view showing a push-up member of a lift mechanism for an object-to-be-processed.

FIG. 3A is a side view showing the structure of a push-up pin.

FIG. 3B is a cross-sectional view showing the structure of the push-up pin.

FIG. 4A is an operation-explanatory diagram to explain how a lift mechanism for an object-to-be-processed operates.

FIG. 4B is an operation-explanatory diagram also to explain how the lift mechanism for an object-to-be-processed operates.

FIG. 5A is a plane view of the push-up pin, wherein a communication path is open laterally at the upper-end portion of a pin body.

FIG. 5B is a cross-sectional view of the push-up pin viewed in the direction of arrows A-A in FIG. 5A.

FIG. 5C is a side view of the push-up pin viewed in the direction of arrows B-B in FIG. 5A.

FIG. 6A is a side view of a push-up pin in which a collar portion has a convex curved surface.

FIG. 6B is a cross-sectional view of the push-up pin in which a collar portion has a convex curved surface.

FIG. 7A is a side view of a push-up pin in which a collar portion forms a convex curved surface and a communication path is open laterally at the upper-end portion of the pin body.

FIG. 7B is a cross-sectional view of the push-up pin in which a collar portion forms a convex curved surface and a communication path is open laterally at the upper-end portion of the pin body.

FIG. 7C is a plane view of the push-up pin in which a collar portion forms a convex curved surface and a communication path is open laterally at the upper-end portion of the pin body.

FIG. 8A is a side view of a push-up pin whose upper-end portion is formed into a conical shape.

FIG. 8B is a cross-sectional view of the push-up pin whose upper-end portion is formed into a conical shape.

FIG. 9 is a partial cross-sectional view showing a push-up pin with an opening provided in the side wall of the lower-end portion thereof.

FIG. 10 is a cross-sectional view showing the push-up pin shown in FIGS. 3A and 3B as Type A with an opening provided therein.

FIG. 11 is a partial cross-sectional view showing a push-up pin whose lower-end portion is secured to a push-up member.

FIG. 12 is a cross-sectional block diagram showing a lift mechanism for an object-to-be-processed according to another embodiment of the present invention, wherein a projection or a collar is provided on a positioning drive pin.

FIG. 13 is a cross-sectional block diagram showing a lift mechanism for an object-to-be-processed according to a modification of the embodiment referred to with respect to FIG. 12.

FIG. 14 is a cross-sectional block diagram showing a lift mechanism for an object-to-be-processed according to yet another embodiment of the present invention, wherein a projection is provided on a communication path.

FIG. 15 is a cross-sectional block diagram showing a lift mechanism for an object-to-be-processed according to yet another embodiment of the present invention, wherein a reduced-diameter portion is provided to a communication path.

FIG. 16 is a cross-sectional block diagram showing a lift mechanism for an object-to-be-processed according to yet another embodiment of the present invention, wherein an evaginated portion is provided on a positioning drive pin and a narrowed portion is provided to a communication path.

FIG. 17 is a cross-sectional block diagram showing a lift mechanism for an object-to-be-processed according to yet another embodiment of the present invention, wherein a projection is provided at the lower end of a pin-insertion hole.

FIG. 18A is a block diagram showing a conventional lift mechanism for an object-to-be-processed provided on a mount stand of a processing apparatus.

FIG. 18B is a block diagram also showing a conventional lift mechanism for an object-to-be-processed provided on a mount stand of a processing apparatus.

### BEST EMBODIMENTS FOR REALIZING THE INVENTION

An embodiment of a lift mechanism for an object-to-be-processed and a processing apparatus using the same according to the present invention will be hereinafter explained with reference to the attached drawings.

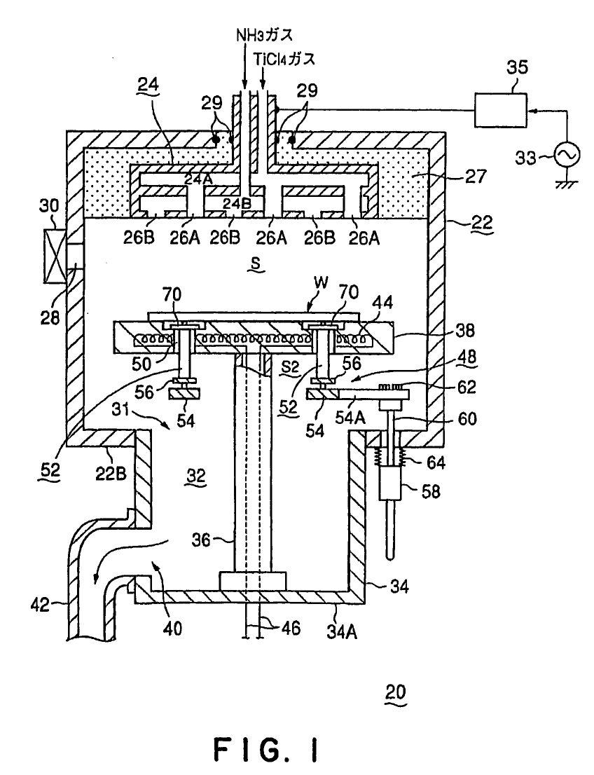

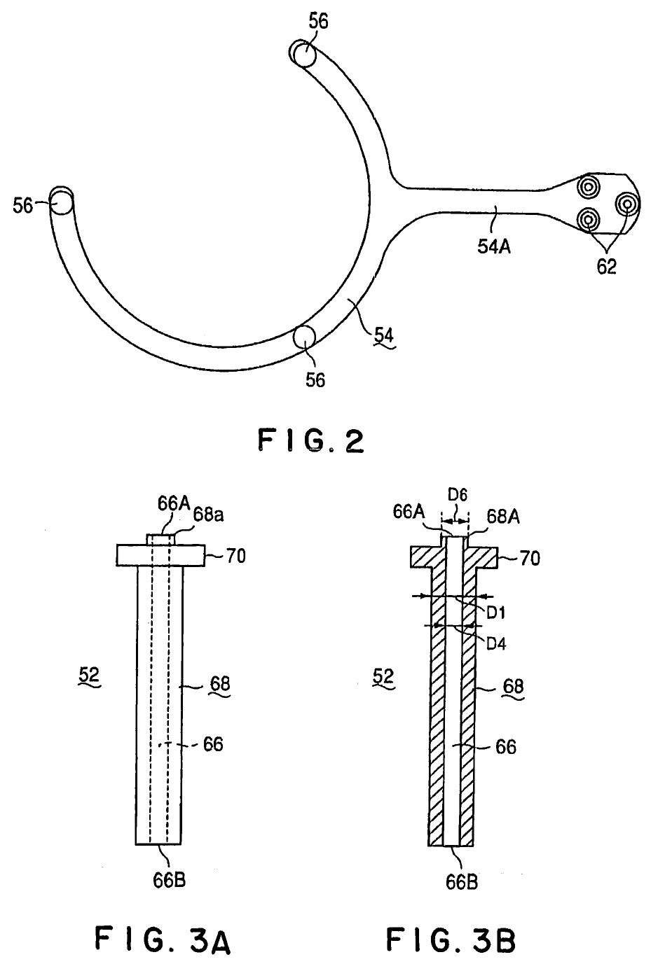

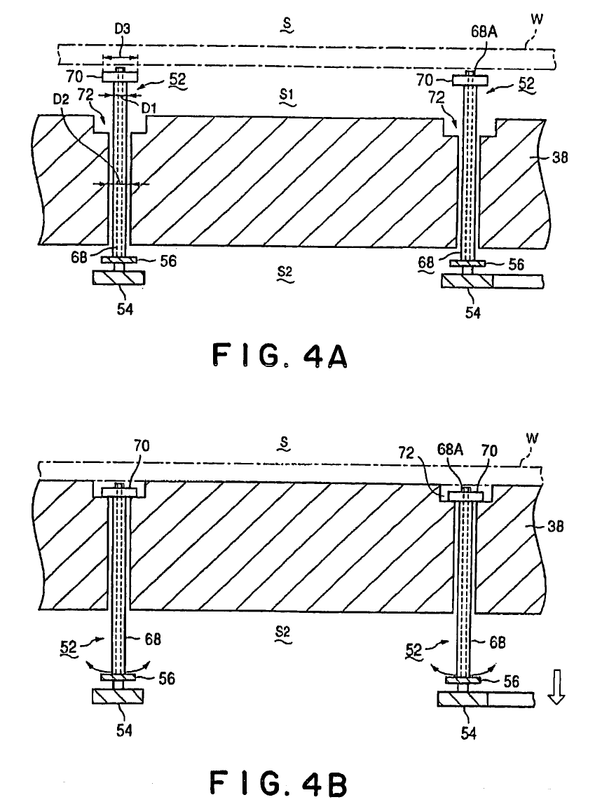

FIG. 1 is a cross-sectional block diagram showing a processing apparatus according to the present invention, FIG. 2 is a plane view showing a push-up member of a lift mechanism for an object-to-be-processed, FIGS. 3A and 3B are diagrams showing the structure of a push-up pin (Type A) and FIGS. 4A and 4B are operation-explanatory diagrams to explain how a lift mechanism for an object-to-be-processed operates. For convenience of explanation, processing of TiN film deposition is employed by way of example.

As shown diagrammatically, this processing apparatus 20 has a processing container 22 which has a interior with a substantially circular shape in cross-section, for instance, and is made of aluminum. At the ceiling area inside this processing container 22, a showerhead structure 24 is provided as a gas feeder to introduce TiCl₄ gas, NH₃ gas, etc. for example, wherein a number of gas injection hole 26A's and 26 B's provided on the lower surface of this showerhead structure 24 emit a processing gas toward a processing space S.

This showerhead structure 24 is divided inside into two separate sections, for example, of gas spaces 24A and 24B with which the aforementioned gas injection holes 26A and 26 B are communicated respectively so that two kinds of gas via separate paths can be mixed only in the processing space S without being mixed in the first place inside the showerhead structure 24. Such gas supplying system is called post mix.

The entire showerhead structure 24 is formed from an electric conductor such as nickel alloy e.g. nickel, hastelloy, etc. and also is combined as an upper electrode. The outer-circumferential side and upper side of this showerhead structure 24 as an upper electrode are entirely covered with an insulator 27 composed of silicon dioxide, alumina (Al₂0₃), etc., for example, to insulate the surface in contact with the processing container 22, and the showerhead structure 24 is fixed to the face of the processing container 22 with this insulator 27 lying therebetween for insulation. In this case, airtightness within the processing container 12 can be maintained by a sealing member 29 such as an o-ring for example inserted into every joint among the showerhead structure 24, the insulator 27 and the processing container 22.

In addition, a high-frequency power source 33 may be connected, which generates a high-frequency voltage of 450 KHz for example, with the showerhead structure 24 via a matching circuit 35 so that a high-frequency voltage can be impressed as necessary on the aforementioned showerhead structure 24 as an upper electrode. In this connection, the frequency of this high-frequency voltage is not limited to 450 KHz but can include other frequencies, such as 13.56 MHz for example.

Further, on a side wall 22A of the processing container 22, a load/unload opening 28 is provided to load and unload a semiconductor wafer W as an object-to-be-processed into the processing container 22, and a gate valve 30 is provided to this load/unload opening 28, which is arranged to be openable and closable airtightly.

Further, an exhaust-air downflow space 32 is formed at a bottom part 22B of the processing container 22. In more specific terms, a wide opening 31 is formed in the center of this bottom part 22B of the container, and this opening 31 is interconnected to a cylindrical section wall 34 which is cylindrical in shape, has a base and extends downwardly to form the exhaust-air downflow space 32 therein. On a bottom part 34A of the cylindrical section wall 34 which blocks the exhaust-air downflow space 32, a supporting column 36 is raised which is cylindrical in shape for example, and a mount stand 38 is secured to the upper-end portion of this supporting column 36, and a lower electrode in the form of a meshed disk, not shown, is implanted into this mount stand 38.

The entrance opening of the exhaust-air downflow space 32 is arranged to have a smaller diameter than that of the mount stand 38 so that a processing gas can flow down outside the peripheral portion of the mount stand 38, enter the area below the mount stand 38, and flow into the entrance opening. In addition, a vacuum vent 40 which is open to the exhaust-air downflow space 32 is formed in the lower portion of the cylindrical section wall 34, and an exhaust pipe 42 in which a vacuum pump, not shown, is inserted is connected to this vacuum vent 40 so that the atmosphere inside the processing container 22 and in the exhaust-air downflow space 32 can be vacuumed.

Further, a pressure control valve with an opening control function, not shown, is inserted intermediately in the exhaust pipe 42. By automatically adjusting the opening of this pressure control valve, the pressure inside the processing container 22 can hold at a constant value or quickly change to achieve an intended pressure.

Furthermore, the mount stand 38 has a resistance heater 44 therein as a heating means aligned in a specific pattern for example. The exterior of this resistance heater 44 is composed of sintered ceramic made of AlN or the like for example, and a semiconductor wafer W as an object-to-be-processed can be mounted thereon. In addition, an electric power feeder 46 disposed through inside the supporting column 36 is connected with the resistance heater 44 to controllably feed electricity.

In this mount stand 38, a lift mechanism 48 for an object-to-be-processed is provided which features the present invention. In more specific terms, the mount stand 38 has plurality of pin-insertion holes 50 e.g. three holes (only two of them are exemplified in FIG. 1) vertically pierced therethrough, and the lift mechanism 48 has a push-up pin 52 inserted through each of these pin-insertion holes 50 in loose fit allowing upward-and-downward movement. At each lower end of the push-up pin 52, a push-up member 54 is positioned which is shaped to provide a circular arc, i.e. a continuous portion of a circle ring, as shown also in FIG. 2, and is made of ceramic such as alumina. Each push-up pin 52 is supported on this push-up member 54 in a manner that each push-up pin 52 is mounted disengageably at its lower end on the upper surface of the push-up member 54. That is to say, the push-up member 54 and the push-up pin 52 can slide relative to each other while the lower end of the push-up pin 52 is supported. In more specific terms, this arc-shaped push-up member 54 is provided with pin-supporting plates 56 positioned thereon spaced apart at 120 degrees relative to the center thereof, and the upper surface of each of these pin-supporting plates 56 receives the lower end of the push-up pin 52 for support. Using a bolt 62, an arm portion 54A extended from this push-up member 54 is interconnected to the upper end of an in/out rod 60 of an actuator 58 which is provided on the lower-surface side of the bottom part 22B, and thus each push-up pin 52 is projected upwardly over the upper end of each of the pin-insertion holes 50 when transferring a wafer W. In addition, the in/out rod 60 of the actuator 58 pierces through the bottom part 22B, and an elastic bellows 64 is inserted under the pierced part of the bottom part 22B so that the in/out rod 60 can move upwardly and downwardly while airtightness inside the processing container 22 is maintained.

Meanwhile, the entire push-up pin 52 featuring the present invention is formed from alumina for example and is hollow inside forming a pipe-like shape which is constructed as a communication path 66, as shown in FIGS. 3A, 3B and FIGS. 4A, 4B. Consequently, the space S1 between the backside surface of a wafer W and the upper surface of the mount stand 38 and the space S2 on the side of backside surface of (under) the mount stand 38 can be communicated, as shown in FIG. 4A.

This push-up pin 52 comprises a pin body 68 formed to have a pipe-like shape and a collar portion 70 having an enlarged diameter provided at the end portion of this pin body 68, through both of which the communication path 66 is provided piercing vertically. In this connection, this collar portion 70 can be formed in any shape including a bamboo-hat shape and curved shape, for example. In addition, an annular portion 68A which is projected above the collar portion 70 is configured to have a smaller diameter than that of the pin body 68.

In view of the above, an upper opening 66A of the communication path 66 is open upwardly at the upper end of the pin body 68, and a lower opening 66B of the communication path 66 is open downwardly at the lower end of the pin body 68.

Regarding configuration settings, an outside diameter D1 of the pin body 68 is approximately 2.8 to 4.8 mm and an inside diameter D2 of the pin-insertion hole 50 is approximately 3 to 5 mm, and a diameter D3 of the collar portion 70 is approximately 3 to 7 mm to provide a larger diameter than the inside diameter D2 of the pin-insertion holes 50, and a recess 72 is formed on the upper surface of the mount stand 38 providing sufficient dimensions to accommodate the collar portion 70. Additionally, an inside diameter D4 (refer to FIG. 3B) of the communication path 66 is approximately 1 to 4 mm. Furthermore, the clearance between the inside diameter D2 of the pin-insertion holes 50 and outside diameter D1 of the pin body 68 is approximately 0.1 to 0.5 mm, preferably approximately 0.2 to 0.4 mm.

In this manner, once the push-up member 54 moves downwardly to the lowermost bottom, the collar portion 70 sinks into the recess 72 of the mount stand 38, and the push-up pin 52 is supported by the pin-supporting plate 56, as shown in FIG. 4B. Alternatively, the push-up pin 52 can be held by the collar portion 70 settled down in the recess 72 of the mount stand 38 whereas the whole push-up pin 52 is separated from the push-up member 54.

In the next explanation, the processing apparatus and the lift mechanism for an object-to-be-processed structured as described above will be explained regarding how they operate.

Prior to transfer of a semiconductor wafer W, firstly, the processing container 22 of the processing apparatus 20, connected for example to a load lock chamber, not shown, is maintained in a high vacuum state inside, and the temperature of the mount stand 38 on which a wafer W is mounted is raised to a predetermined temperature by the resistance heater 44 as a heating means and maintained stable.

Under these arrangements, an unprocessed semiconductor wafer W is held by a transfer arm, not shown, and loaded into the processing container 22 by way of the gate valve 30 switched to an open form and the load/unload opening 28, and transferred onto the push-up pins 52 that are raised as shown in FIG. 4A, and then mounted and supported on the upper surface of the mount stand 38 by moving the push-up members 54 downwardly in order to move these push-up pins 52 down. Next, processing gases such as TiCl₄ gas and NH₃ gas for example are emitted and fed from the showerhead structure 24 through the gas injection holes 26A and 26 B respectively and are mixed in the processing space S. Then, the atmosphere in the processing container 22 and the exhaust-air downflow space 32 is vacuumed by proceeding driving a vacuum pump provided to the exhaust pipe 42, though not shown. And then, the atmosphere of the processing space S is maintained at a predetermined processing pressure by adjusting the valve opening of a pressure control valve. As a result, TiCl₄ and NH₃ deposit a TiN film on the front-side surface of a semiconductor wafer W through thermal reaction. Alternatively, film can be deposited using plasma generated in the processing space S by applying high-frequency power between the showerhead structure 24 as an upper electrode and the mount stand 38 as a lower electrode.

The progress of the transfer process of a wafer W onto the mount stand 38 will be hereinafter explained in detail.

As described above, when the push-up members 54 are moved downwardly by driving the actuator 58 (refer to FIG. 1) while a wafer W is supported on the upper ends of the push-up pins 52 raised to the uppermost position, the push-up pins 52 supported by the push-up members 54 themselves also move downwardly integrally with the push-up members 54 as a result. As shown in FIG. 4B, the collar portion 70 at the upper portion of each of the push-up pins 52 down below sinks into the recess 72 in the upper surface of the mount stand 38, and at this point, the wafer W supported by the push-up pins 52 is transferred to and positioned on the upper surface of the mount stand 38 accordingly. Further, the entire body of the push-up pin 52 supported by the pin-supporting plates 56 provided on the push-up member 54 is supported as it is. Alternatively, the push-up pin 52 can be supported by the collar portion 70 whereas the collar portion 70 is down in the recess 72 of the mount stand 38.

At this point in a case of using a conventional apparatus, the gas in the space S1 between the backside surface of a wafer and the mount stand 38 cannot quickly escape through the clearance between the push-up pin 52 and the pin-insertion hole 50 completely at the time a wafer W is moved down, as previously referred to, and consequently the wafer can possibly sideslip on the upper surface of the mount stand 38 out of alignment, though only slightly, resulting from the air-cushion effect.

In a case of using the apparatus according to the present invention, however, the above-mentioned air-cushion effect is hardly created because the gas in the space S1 can be quickly discharged toward the space S2 under the mount stand 38 through the communication path 66 formed in the push-up pin 54, and as a result, the wafer W can be held at the correct position on the mount stand 38 without causing sideslip or displacement.

That is to say, when a wafer W is moved downwardly to make contact with the upper surface of the mount stand 38 and mounted thereon, the gas in the space S1 on the side of the backside surface of the wafer W enters the communication path 66 formed in the pin body 68 of each push-up pin 52 to be evacuated therethrough to the space S2 under the mount stand 38. Specifically, since the space S2 is vacuumed at the lower location, the gas in the space S1 is discharged more quickly, thus preventing causing displacement of a wafer W, without creating the air-cushion effect as mentioned above.

In this case, the upper opening 66A of this communication path 66 is blocked by the backside surface of a wafer W and the lower opening 66B is blocked by the upper surface of the push-up member 54 until the wafer W is mounted on the mount stand 38. However, observing these parts microscopically, these openings 66A and 66B are not completely blocked but leave enough space for gas to flow, and thus the gas evacuation from the space S1 is not quite disturbed.

Moreover, as described above, the gas in the space S1 is discharged mainly through the communication path 66 and does not flow into the clearance formed between the inner wall of the pin-insertion hole 50 and the outer circumferential surface of the push-up pin 52 which is too narrow. Consequently, unnecessary film deposition on this clearance can be prevented even when a precoat film is formed in advance on the mount stand 38 before film deposition is performed on a wafer W or by a film deposition gas flowing into this clearance during film deposition on a wafer W, and thus the vertical operation of the push-up pin 52 can be performed smoothly, without being disturbed.

Moreover, since the lower end of each push-up pin 52 is not fixed onto the pin-supporting plates 56 of the arc-shaped push-up member 54 but only supported thereon without being separated therefrom to be able to slide therewith, the push-up pin 52 can be still accepted even in case of heat expansion/contraction of the arc-shaped push-up member 54 and the push-up pin 52 is also prevented from being damaged by the contact load from the pin-insertion hole 50 caused by the heat expansion/contraction of the push-up member 54.

In the above embodiment, the communication path 66 is open upwardly from the annular portion 68A. On the contrary, the communication path 66 can open laterally at the upper portion of the pin body 68, instead.

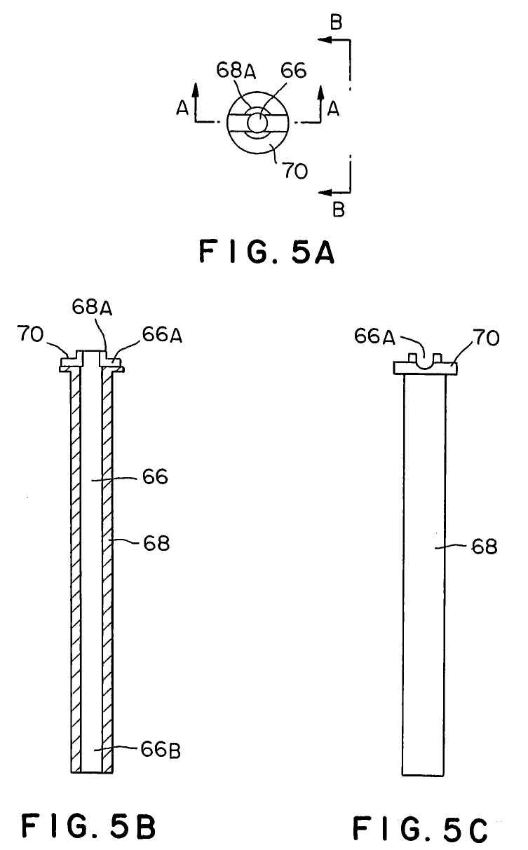

A push-up pin 52 is shown in FIGS. 5A, 5B and 5C wherein the communication path 66 is open laterally at the upper portion of the pin body 68. FIG. 5A is a plane view of the push-up pin 52 viewed from above, FIG. 5B is a sectional side view of the push-up pin 52 viewed in the direction of arrows A-A in FIG. 5A and FIG. 5C is a side view of the push-up pin 52 viewed in the direction of arrows B-B in FIG. 5A.

As shown in FIGS. 5A, 5B and 5C, the annular portion 68A is partially cut and the collar portion 70 has a channel formed at one part, according to the present invention. The structure in this way allows the communication path 66 to open laterally at the upper-end portion as shown obviously in FIG. 5B. In this case, the opening 66A on the upper side of the communication path 66 is not blocked by the backside surface of a wafer W when the wafer W is mounted on the annular portion 68A. Consequently, gas circulation is facilitated and the gas in the space S1 thus can easily be discharged.

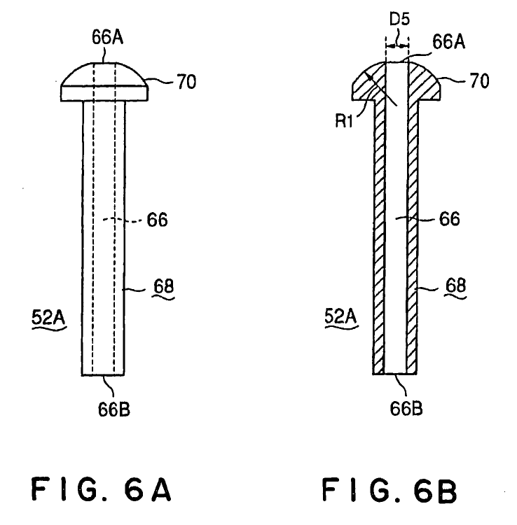

Although the collar portion 70 at the upper portion of the push-up pin 52 is formed into a flat-plate shape in the above embodiment, the shape is not limited but also can be formed into a shape of an upwardly-convex curved surface (Type B) as shown in FIGS. 6A, 6B and 6C.

FIGS. 6A, 6B and 6C are diagrams showing a modification of the push-up pin of this type, wherein FIG. 6A is a side view, FIG. 6B is a cross-sectional view. In a push-up pin 52A of this modification as shown diagrammatically, the collar portion 70 is formed into a shape of an upwardly-convex curved surface with a specific a radius of R1, approximately 3 to 8 mm for example. An opening 66A at the upper portion of the communication path 66 is formed by opening the center portion of above-mentioned collar portion 70 upwardly.

In this manner, the contact area between a wafer W and the 66A of Type B directly contacting with the backside surface of the wafer W (refer to FIG. 6B) is smaller than the contact area in the case of Type A shown in FIG. 3B, and thus an operational advantage of minimizing the amount of displacement of a wafer W can be achieved even if the push-up pin 52A slightly inclines off the vertical line when moving upwardly or downwardly, because the contact surface of the collar portion 70 of the above-mentioned Type B with the backside surface of the wafer W has a curved surface and is thus small.

The opening 66A at the upper portion of the communication path 66 is not limited to be formed to open upwardly at the upper end of the pin body 68 as in the above modification but also can be formed to open laterally at the upper-end portion of the pin body.

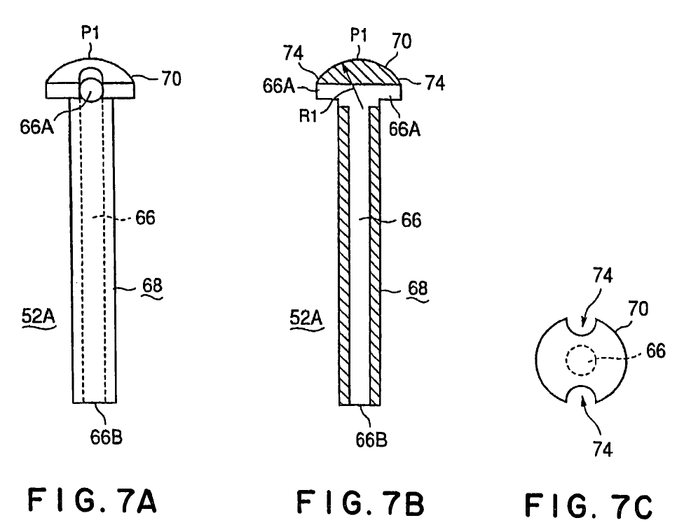

Such modification of the push-up pin 52 is shown in FIGS. 7A, 7B and 7C, wherein FIG. 7A is a side view, FIG. 7B is a cross-sectional view and FIG. 7C is a top view. As shown diagrammatically, the collar portion 70 of a push-up pin 52B in this modification is formed into a shape of an upwardly-convex curved surface (dome-like or bamboo-hat shape) with a specific radius of R in the same manner as the modification shown in FIGS. 6A and 6B. However, the opening 66A at the upper portion of the communication path 66 is open laterally or horizontally at the upper-end portion of this push-up pin 52 instead of being open upwardly. The drawings show the opening 66A formed to open to the both sides in opposite directions to the right and to the left. In this case, a channel 74 is formed at one part of the collar portion 70 as shown in FIG. 7C, and this channel 74 forms a part of the opening 66A.

In this manner, a wafer W is supported by the top P1 of this dome-like collar portion 70 contacting with the backside surface of the wafer W providing a point contact so to speak, and thus an operational advantage of further minimizing the amount of displacement of a wafer W can be achieved even if the push-up pin 52B slightly inclines off the vertical line when moving upwardly or downwardly as described above, because the wafer W is supported in the point contact condition.

Furthermore, in the embodiment in FIGS. 3A and 3B or the modification in FIGS. 6A and 6B, a minor exhaust resistance still exists due to the upper opening 66A partly blocked by directly contacting with the backside surface of a wafer W. However, in the modification in these FIGS. 7A and 7B, the opening 66A is constantly open without being blocked by a wafer W due to the opening 66A opening laterally, which fact enables the gas in the space S1 on the side of the backside surface of the wafer W to discharge by just that much more quickly, and consequently displacement of a wafer W can be further minimized.

Although the push-up pin 52 in which the collar portion 70 is provided at the upper portion of the pin body 68 has been explained according to the embodiment in FIGS. 3A and 3B, the modification in the FIGS. 5A, 5B and 5C, FIGS. 6A and 6B and FIGS. 7A, 7B and 7C, the present invention is not limited to those embodiment and modifications but also include a push-up pin having a structure without the collar portion 70.

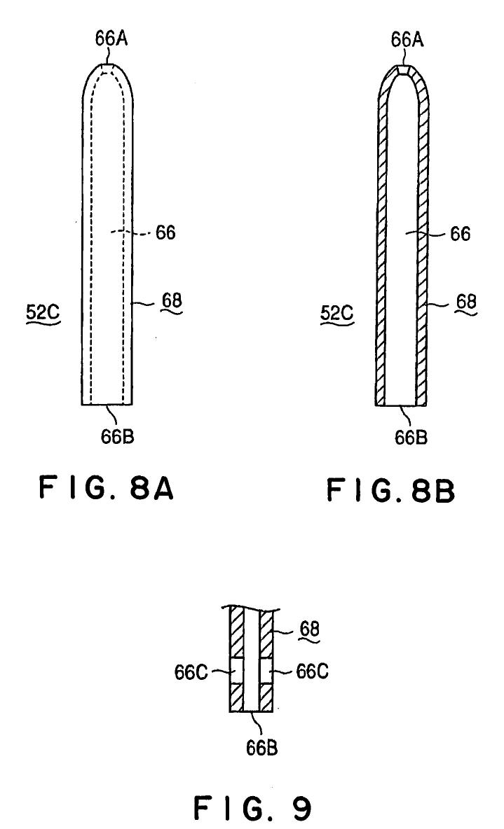

FIGS. 8A and 8B show such a modification of the present invention, wherein FIG. 8A is a side view and

FIG. 8B is a cross-sectional view. As shown diagrammatically, a push-up pin 52C according to this modification has no collar portion 70 that has an enlarged diameter (refer to FIGS. 7A, 7B and 7C), and the upper portion of the pin body 68 through which the communication path 66 is formed is formed into a conical shape by gradually decreasing the diameter thereof, the end portion of which is opened to provide the upper opening 66A.

Since the collar portion 70 is not provided in this case, this push-up pin 52C is not supported by the mount stand 38 but constantly held by the lower end thereof on the push-up member 54 (refer to FIGS. 4A and 4B).

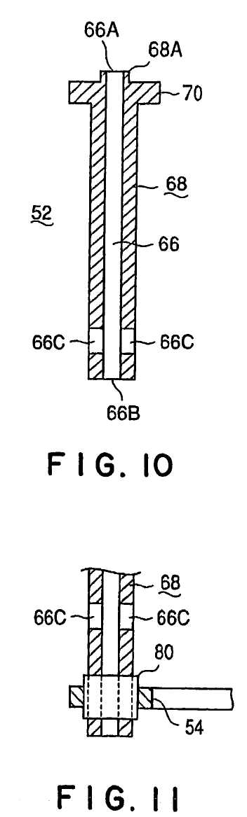

In addition, although the lower opening 66B is formed in the lower end of the pin body 68 in the above embodiment and each of the modifications, an opening 66C that is open laterally can be provided alternatively or additionally by opening for example the side wall at the lower portion of the pin body 68 (push-up pin) as shown in the cross-sectional view in FIG. 9. In this drawing, the additional opening 66C which is open to the both sides is provided. This opening 66C is not limited to be formed in the lower-end portion of the pin body 68 but also in any intermediate part. FIG. 10 is a cross-sectional view showing the state that the push-up pin 52 of Type A shown in FIGS. 3A and 3B is provided with the above-mentioned opening 66C.

In this manner, the opening 66C at the lower portion of the push-up pin is constantly open without being blocked by the push-up member 54, thereby enabling the gas in the space S1 on the side of the backside surface of a wafer W (refer to FIG. 4A) to discharge more quickly toward the space S2 on the side of the backside surface of the mount stand 38.

Moreover, in a case that the lower opening 66C is formed in the side wall of the lower-end portion of the pin body 68 as shown in FIG. 9, the push-up member 54 can be connected with the lower-end portion of the pin body 68 by a vertical clamp screw 80 to support the pin body 68, as shown in FIG. 11.

In the next place, another embodiment according to the present invention will be explained.

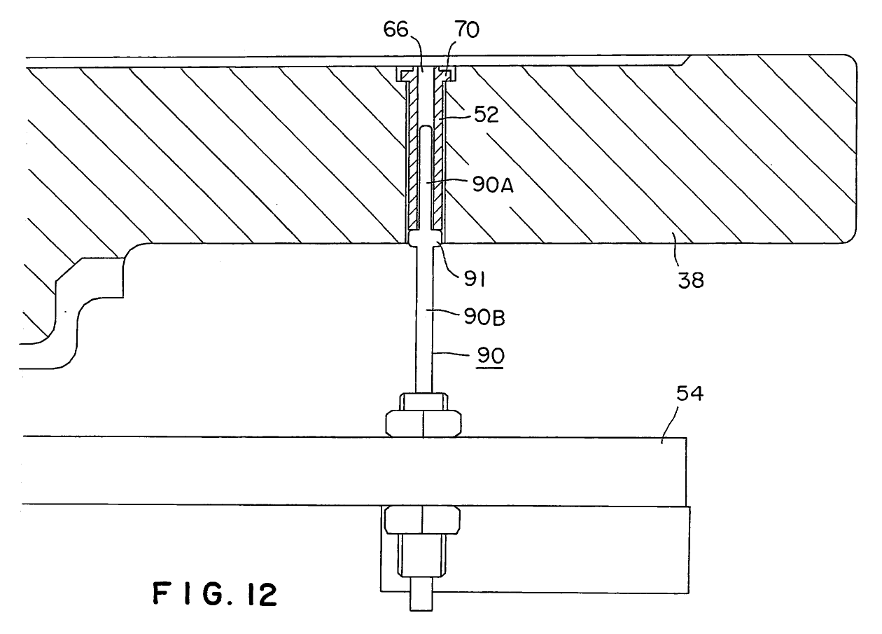

FIG. 12 shows a lift mechanism for an object-to-be-processed according to the present embodiment. As shown in FIG. 12, the push-up pin 52 is formed shorter, and an upper-end portion 90A of a positioning drive pin 90 is slidably inserted into the communication path 66, in which the positioning drive pin 90 positions and vertically drives the push-up pin 52 according to the present embodiment.

The outside diameter of the upper-end portion 90A of the positioning drive pin 90 is formed preferably slightly smaller than the inside diameter of the communication path 66 thereby forming a clearance between the outer circumferential surface of the upper-end portion 90A and the inner surface of the communication path 66.

In the outer circumferential surface of the upper-end portion 90A of the positioning drive pin 90, plurality of grooves can be formed in a longitudinal direction of the pin. In this case, the part with a maximum outside diameter of the upper-end portion 90A of the positioning drive pin 90 positions the push-up pin 52 while the grooves can ensure space for gas circulation. Instead of providing the grooves, the upper-end portion 90A of the positioning drive pin 90 can be formed square in transverse section, for example. This modification is also applicable to each embodiment hereinafter explained.

The upper-end portion 90A of the positioning drive pin 90 can be also formed to have a relatively smaller diameter than that of the lower-end portion 90B of the positioning drive pin 90 in order to ensure a clearance from the inner surface of the communication path 66 and rigidity of the positioning drive pin 90.

On a portion of the positioning drive pin 90, a projection or collar 91 is formed as shown in FIG. 12. This projection or collar 91 is dimensioned to engage the lower-end portion of the push-up pin 52. In a case that the projection or collar 91 is a projection, the projection may require comprising a plurality of projections which project radially outwardly from the outer circumferential surface of the positioning drive pin 90. As a result of a plurality of clearances among these plurality of projections which project radially outwardly, the communication path 66 is not blocked and thus gas can easily circulate. Likewise in a case that the projection or collar 91 is a collar, there is a clearance between the collar and the lower-end portion of the push-up pin 52 under microscopical observation, and thus the gas between a wafer W and the mount stand 2 when moving the push-up pin 52 downwardly can duly discharge.

The lower-end portion of the positioning drive pin 90 is secured to the push-up member 54.

Once the positioning drive pin 90 is raised from the state shown in FIG. 12, the projection or collar 91 engages the lower-end portion of the push-up pin 52 and moves the push-up pin 52 upwardly to lift a wafer W. Then, once the positioning drive pin 90 moves downwardly from the state shown in FIG. 12, the head portion of the push-up pin 52 sinks into the recess 72 of the mount stand 38 and the collar portion 70 and the mount stand 38 are fastened.

The push-up pin 52 can always support a wafer W at specific positions with the lift mechanism for an object-to-be-processed of the present invention because the position of the push-up pin 52 is specified by the position of the positioning drive pin 90 and the position of the positioning drive pin 90 is specified by the position of the push-up member 54.

According to the lift mechanism for an object-to-be-processed of the present invention, the push-up pin 52 is held in a vertical position by the positioning drive pin 90, thus smoothly moving the push-up pin 52 upwardly and downwardly and preventing the push-up pin 52 from inclining that inhibits the upward-downward movement.

Likewise the lift mechanism for an object-to-be-processed described above in the other embodiments, the gas between a wafer W and the mount stand 38 escapes into the space S2 under the mount stand 38 through the communication path 66 so that displacement of the wafer W is prevented.

Although the push-up member 54 fixes the lower-end portion of the positioning drive pin 90 thereon according to the present embodiment, the push-up member 54 can slidably hold the lower-end portion of the positioning drive pin 90 thereon in a case that positioning by the positioning drive pin 90 is not highly required. In this instance, the impact from heat expansion/contraction of the push-up member 54 can be reduced.

Although the push-up pin 52 is formed short enough to be accommodated within the mount stand 2 according to the present embodiment, the push-up pin 52 can project downwardly from the lower surface of the mount stand 2.

Furthermore, although the length of the maximum outside diameter of the projection or collar 91 is shorter than the inside diameter of the pin-insertion hole 50 so that the projection or collar 91 can proceed into the pin-insertion hole 50 according to the present embodiment, the projection or collar 91 can be formed in a manner that the maximum outside diameter thereof is longer than the inside diameter of the pin-insertion hole 50.

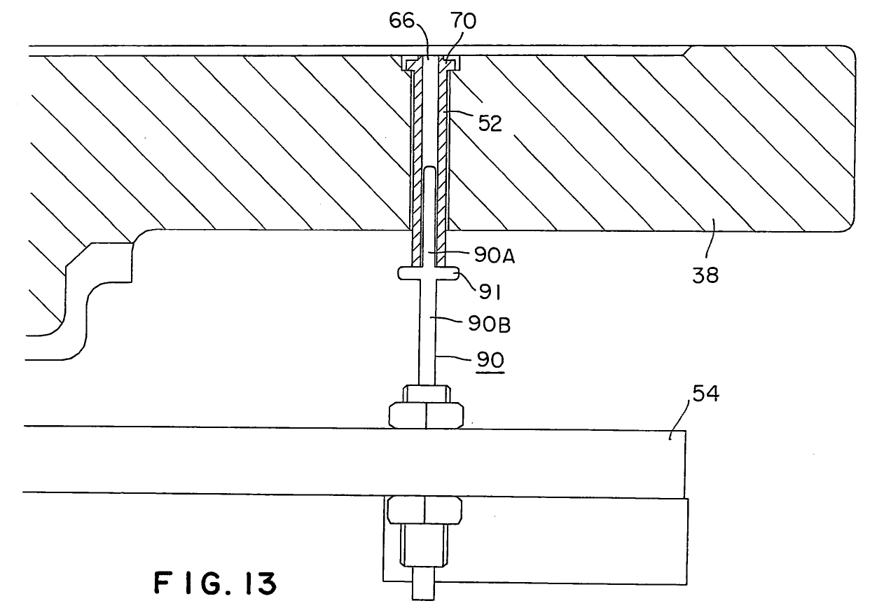

FIG. 13 shows an embodiment comprising two configurations that the lower-end portion of the push-up pin 52 projects downwardly from the lower surface of the mount stand 2 and the length of the maximum outside diameter of the projection or collar 91 is longer than the inside diameter of the pin-insertion hole 50 of the mount stand 2.

According to the embodiment shown in FIG. 13, whereas all of the operational advantages of FIG. 12 can be fulfilled, the projection or collar 91 engages the lower surface of the mount stand 38 at a specific height when raising the positioning drive pin 90. As a result of specifying the height of the projection of the push-up pin 52 from the upper surface of the mount stand 38 in this way, all the push-up pins 52 can have the equal height of the projection from the upper surface of the mount stand 38.

In the above embodiments of FIGS. 12 and 13, the collar portion 70 can be formed into a convex curved surface as shown in FIGS. 6A and 6B. In addition, the upper opening of the communication path 66 can open laterally as shown in FIGS. 5A, 5B, and 5C and FIGS. 7A and 7B. The upper-end portion of the push-up pin 52 also can be formed into a conical shape by progressively reducing the diameter as shown in FIGS. 8A and 8B.

Moreover, in the above embodiments of FIGS. 12 and 13, an opening that is open laterally can be formed as shown in FIG. 9 by forming an opening in the side wall of the lower-end portion of the pin body 68 of the push-up pin 52.

In the next place, yet another embodiment of the present invention will be explained.

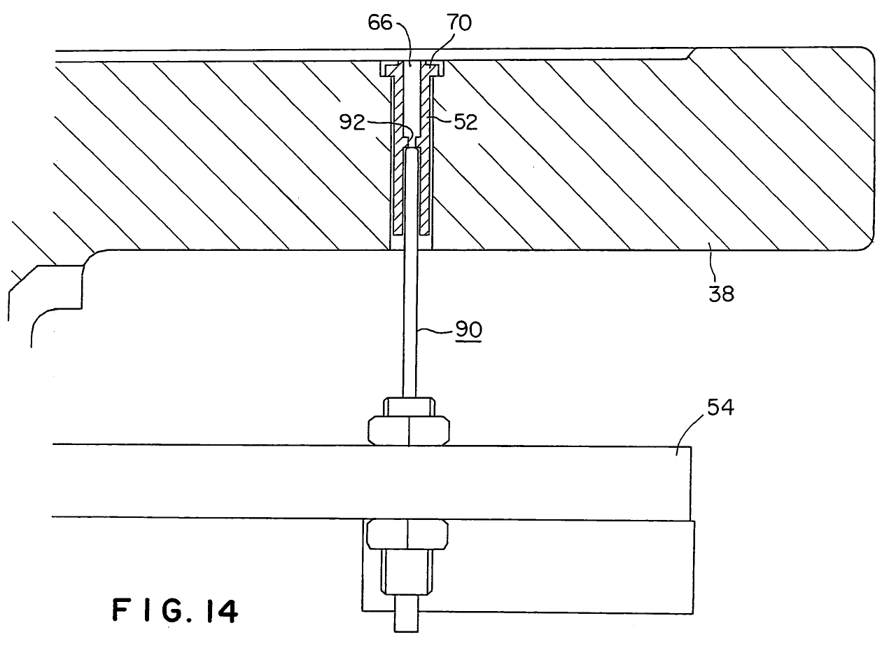

FIG. 14 shows a lift mechanism for an object-to-be-processed according to another embodiment of the present invention.

In the present embodiment, a projection 92 is formed on the communication path 66 of the push-up pin, the projection 92 which engages the upper end of the positioning drive pin 90 when the positioning drive pin 90 is raised, as shown in FIG. 14.

The projection 92 may be formed to extend around the entire circumference of the inner wall of the communication path 66, but also can be a plurality of projections formed discontinuously along the circumference of the inner wall of the communication path 66, projecting inwardly.

According to the present embodiment, the push-up pin 52 is formed short, and the upper-end portion of the positioning drive pin 90 is slidably inserted into the communication path 66.

The projection 92 is formed to have a slightly smaller minimum inside diameter than the outside diameter of the upper-end portion 90A of the positioning drive pin 90. Further, a clearance enough for gas circulation is formed between the positioning drive pin 90 and the communication path 66.

The lower-end portion of the positioning drive pin 90 is fixed to the push-up member 54.

Once the positioning drive pin 90 is raised from the state shown in the FIG. 14, the projection 92 engages the upper end of the positioning drive pin 90 to move the push-up pin 52 upwardly, thereby raising a wafer W. Then, once the positioning drive pin 90 moves downwardly from the state shown in FIG. 14, the head portion of the push-up pin 52 sinks into the recess 72 of the mount stand 38 and the collar portion 70 and the mount stand 38 are fastened.

The lift mechanism for object-to-be-processed according to the present embodiment also can achieve the operational advantages including that the gas between a wafer W and the mount stand 38 escapes through the communication path 66, the position of the push-up pin 52 remains at a fixed location, and the push-up pin 52 is held in a vertical position by the positioning drive pin 90, thus preventing the push-up pin 52 from inclining that inhibits the upward-downward movement.

Moreover, the modifications can be applied also to the lift mechanism for object-to-be-processed according to the present embodiment, including that the push-up member 54 slidably holds the lower-end portion of the positioning drive pin 90 thereon, the lower-end portion of the push-up pin 52 projects downwardly from the lower face of the mount stand 2, the collar portion 70 is formed into a convex curved surface as shown in FIGS. 6A and 6B, the upper opening of the communication path 66 is laterally opened as shown in FIGS. 5A, 5B and 5C and FIGS. 7A and 7B, the upper-end portion of the push-up pin 52 is formed into a conical shape as shown in FIGS. 8A and 8B instead of having the collar portion 70, and an opening is formed in the side wall of the lower-end portion of the pin body 68 of the push-up pin 52 to be open laterally.

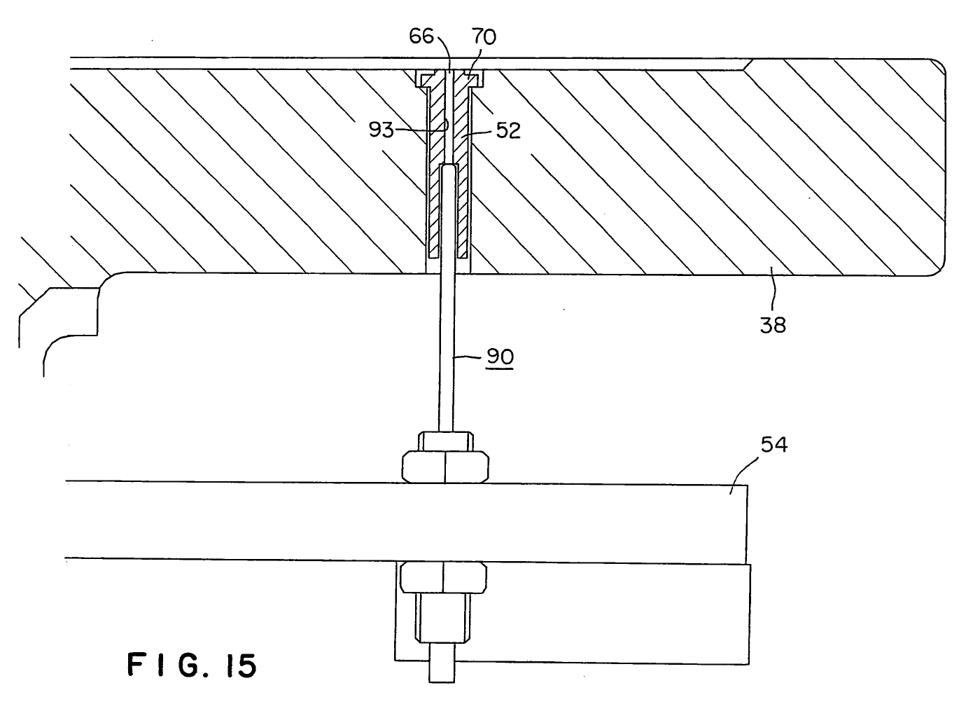

Furthermore, the projection 92 can be replaced by a reduced-diameter portion 93 formed at the upper portion of the communication path 66 as shown in FIG. 15. The inside diameter of the reduced-diameter portion 93 is formed slightly smaller than the outside diameter of the positioning drive pin 90. In this case as well, once the positioning drive pin 90 is raised, the upper-end portion of the positioning drive pin 90 engages the lower end of the reduced-diameter portion 93 to move the push-up pin 52 upwardly. Then, once the positioning drive pin 90 moves downwardly from the state shown in FIG. 15, the head portion of the push-up pin 52 sinks into the recess 72 of the mount stand 38 and the collar portion 70 and the mount stand 38 are fastened.

The diameter of the reduced-diameter portion 93 can be formed only by a predetermined length in the longitudinal direction along the push-up pin 52 and increased to the original diameter beyond the predetermined length. In this case, a shoulder portion engaging the upper end of the positioning drive pin 90 is formed at the lower-end portion of the reduced-diameter portion 93, thus achieving exactly the same operational advantages as in the embodiments of FIGS. 14 and 15.

In the next place, yet another embodiment of the present invention will be explained.

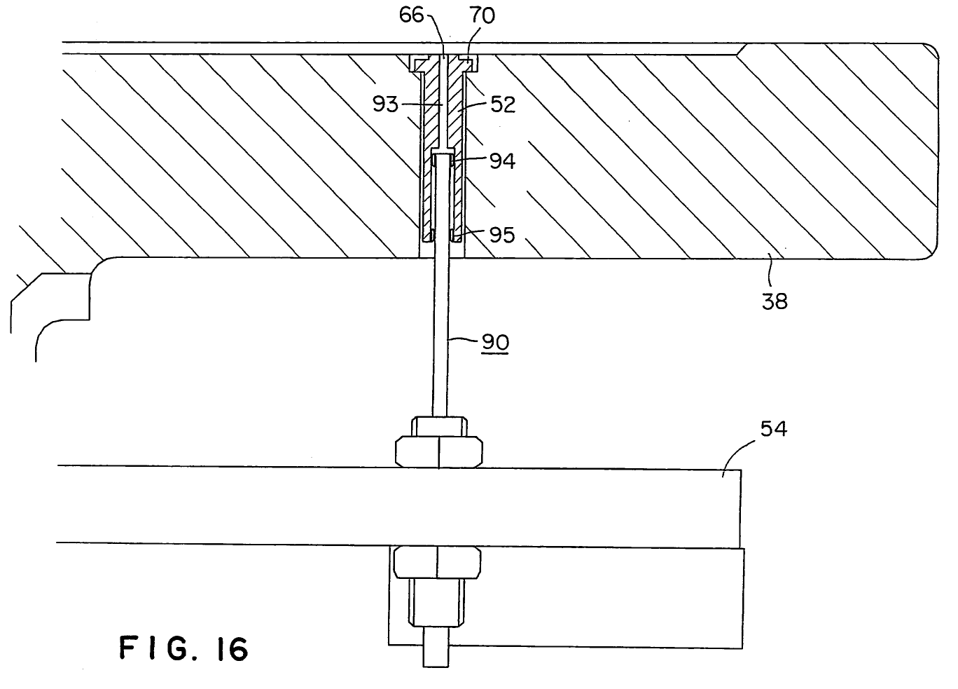

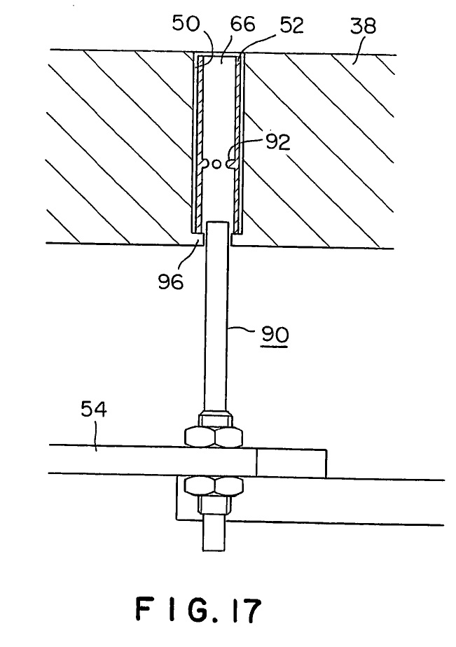

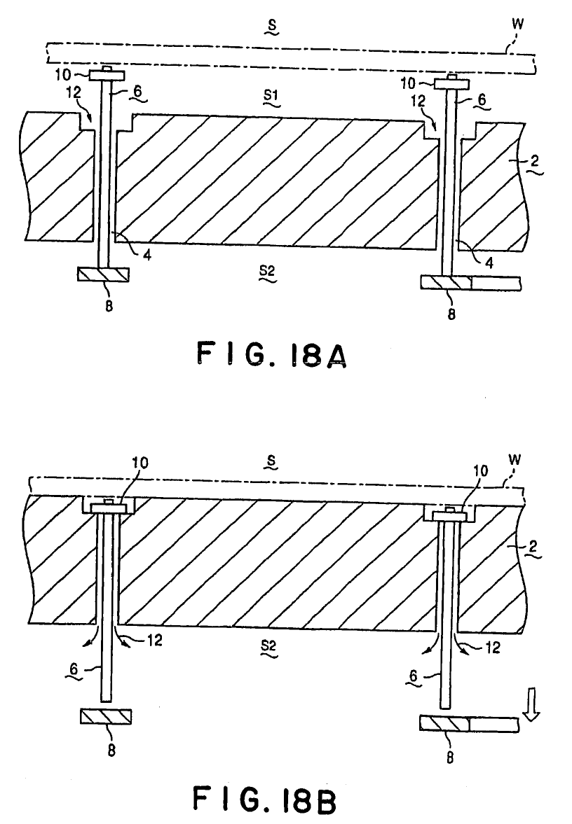

FIG. 16 shows a lift mechanism for an object-to-be-processed according to the present embodiment.

The present embodiment is characterized by having a structure that pulls down the push-up pin 52 assuredly when the push-up pin 52 is moved down.

In the present embodiment, the upper-end portion of the positioning drive pin 90 has an evaginated portion 94 and the lower-end portion of the communication path 66 has a narrowed portion 95, as shown in FIG. 16. The evaginated portion 94 is formed in a manner that the length of the maximum outside diameter is longer than that of the minimum inside diameter of the narrowed portion 95. The evaginated portion 94 and the narrowed portion 95 can be formed by providing screws for example. When the end portion of the positioning drive pin 90 is inserted, the positioning drive pin 90 is screwed for insertion, and during the regular operation, the screw threads engage each other. Instead of the screws, any form of fitting together can be adapted which allows rotation after insertion.

The lower-end portion of the positioning drive pin 90 is secured to the push-up member 54. Once the positioning drive pin 90 is raised from the state shown in the FIG. 16, the reduced-diameter portion 93 of the communication path 66 engages the upper end of the positioning drive pin 90 to move the push-up pin 52 upwardly, thereby raising a wafer W. Assuming that the push-up pin 52 would not move downwardly for some reason when the positioning drive pin 90 moves downwardly in a state that the push-up pin 52 has been moved upwardly, the evaginated portion 94 and the narrowed portion 95 are fastened and thus the push-up pin 52 can be pulled down assuredly. In this manner, the trouble that the push-up pin 52 would not pulled in can be prevented.

The lift mechanism for object-to-be-processed according to the present embodiment can achieve as well the operational advantages including that the gas between a wafer W and the mount stand 38 escapes through the communication path 66, the position of the push-up pin 52 remains at a fixed location, and the push-up pin 52 is held in a vertical position by the positioning drive pin 90.

Moreover, the modifications can be applied also to the lift mechanism for object-to-be-processed according to the present embodiment, including that the lower-end portion of the push-up pin 52 projects downwardly from the lower face of the mount stand 2, the collar portion 70 is formed into a convex curved surface as shown in FIGS. 6A and 6B, the upper opening of the communication path 66 is laterally opened as shown in FIGS. 5A, 5B and 5C and FIGS. 7A and 7B, the upper-end portion of the push-up pin 52 is formed into a conical shape by progressively reducing the diameter as shown in FIGS. 8A and 8B, an opening is formed in the side wall of the lower-end portion of the pin body 68 of the push-up pin 52 to be open laterally, and a projection or shoulder portion can replace the reduced-diameter portion 93.

In the next place, yet another embodiment of the present invention will be explained.

FIG. 17 shows a lift mechanism for an object-to-be-processed according to the present embodiment. In the present embodiment, the lower-end portion of the pin-insertion hole of the mount stand can hold the lower end of the push-up pin.

The mount stand 38 according to the present embodiment has a pin-insertion hole 50, and a projection 96 is formed on the lower-end portion of the pin-insertion hole 50, as shown in FIG. 17. The projection 96 may be formed to extend around the entire circumference of the inner surface of the pin-insertion holes 50, but also can be a plurality of discontinuous projections along the circumference projecting inwardly.

The push-up pin 52 is inserted to fit into the pin-insertion hole 50 from above. The lower end of the push-up pin 52 engages the projection 96. A communication path 66 is formed inside the push-up pin 52. A projection 92 is formed inside the communication path 66. The projection 92 may be formed to extend continuously around the entire circumference of the inner surface of the communication path 66, i.e. ring-shaped. Also, the aforementioned reduced-diameter portion 93 or shoulder portion may be adapted instead of the projection 92.

The upper-end portion of the positioning drive pin 90 is inserted into the communication path 66. The lower-end portion of the positioning drive pin 90 is fixed to the push-up member 54.

According to the present embodiment, once the positioning drive pin 90 is raised, the projection 92 engages the upper end of the positioning drive pin 90 to move the push-up pin 52 upwardly, thereby raising a wafer W. Then, once the positioning drive pin 90 moves downwardly, the downward movement of the push-up pin 52 comes to a halt by engaging the projection 96 at the lower end thereof.

The lift mechanism for object-to-be-processed according to the present embodiment also can achieve the operational advantages including that the gas between a wafer W and the mount stand 38 escapes through the communication path 66, the position of the push-up pin 52 remains at a fixed location, and the push-up pin 52 is held in a vertical position by the positioning drive pin 90, thus preventing the push-up pin 52 from inclining that inhibits the upward-downward movement.

Moreover, the modifications can be applied also to the lift mechanism for object-to-be-processed according to the present embodiment, including that the push-up member 54 slidably holds the lower-end portion of the positioning drive pin 90 thereon, the collar portion 70 is formed as shown in FIGS. 3A and 3B, said collar portion 70 is formed into a convex curved surface as shown in FIGS. 6A and 6B, the upper-end portion of the push-up pin 52 is formed into a conical shape as shown in FIG. 8A and BB, the upper opening of the communication path 66 is laterally opened as shown in FIGS. 5A, 5B and 5C and FIGS. 7A and 7B, and an opening is formed in the side wall of the lower-end portion of the pin body 68 of the push-up pin 52 to be open laterally.

Although processing of TiN film deposition on the surface of a wafer W is explained by way of example in the above embodiments, the present invention is not limited to this case, needless to add, but can be applied to the cases of depositing other kinds of films, or not limited to film deposition for that matter but including the cases of heat treatment, modification, etching, sputtering and the single-wafer processing of every kind using plasma technology.

Also, the object-to-be-processed is not limited to a semiconductor wafer to be applied as exemplified in the present embodiments, needless to say, but also can be LCD substrates, glass substrates, etc.

As explained hereinabove, according to the present invention of the lift mechanism for an object-to-be-processed and the processing apparatus using the same, the superior operational advantages can be achieved as stated below.

According to the present invention, when an object-to-be-processed is mounted on a mount stand, the gas in the space on the side of the backside surface of the object-to-be-processed can be discharged quickly toward the side of the backside surface of the mount stand through a communication path formed in a push-up pin. Consequently, an air-cushion effect is not created, and thus sideslip of the object-to-be-processed out of alignment on the mount stand can be prevented, and displacement of the object-to-be-processed can be prevented as a result.

According to the present invention, a positioning drive pin is inserted into the communication path of the push-up pin so that the push-up pin can be positioned by the positioning drive pin, and thereby displacement of a wafer W can be prevented.

According to the present invention, the vertical operation of the push-up pin can be performed smoothly without causing inclination of the push-up pin inhibiting vertical operation thereof, because the positioning drive pin is inserted into the communication path of the push-up pin so that the push-up pin can be held vertically by the positioning drive pin.

According to the present invention, an opening in the upper portion of the push-up pin is opened laterally so that the opening can be prevented from being blocked by the side of the backside surface of an object-to-be-processed, and thus the gas in the space of the side of the backside surface of the object-to-be-processed can be discharged quickly, smoothly and assuredly.

According to the present invention, because a channel that forms a part of the opening is provided in the collar portion, this opening can be prevented from being blocked by the side of the backside surface of an object-to-be-processed assuredly, and thereby the gas in the side of the backside surface of the object-to-be-processed can be more quickly and assuredly discharged.

According to the present invention, an opening in the lower end of the push-up pin is opened laterally, and thereby this opening can be prevented from being blocked by the push-up member assuredly.

Amendment under PCT Article 34

1. A lift mechanism for an object-to-be-processed including a plurality of pin-insertion holes formed in the mount stand provided inside an evacuatable processing container and a push-up pin inserted through each of said pin-insertion holes, said push-up pin capable of moving upwardly and downwardly, wherein a push-up member moves said push-up pin upwardly and downwardly so as to mount an object-to-be-processed on said mount stand, the lift mechanism characterized in that
said push-up pin is structured to have a communication path formed therein so as to communicate the spaces above and below said mount stand.

2. A lift mechanism for an object-to-be-processed according to claim 1, the lift mechanism characterized in that
said push-up pin comprises:
a pin body; and
a collar portion provided on the end portion of said pin body, said collar portion being held by the peripheral portion of an opening in the upper end of said pin-insertion hole when said push-up pin is moved downwardly.

3. A lift mechanism for an object-to-be-processed according to claim 2, the lift mechanism characterized in that
an upper opening of said communication path is opened upwardly at the upper-end portion of said pin body.

4. A lift mechanism for an object-to-be-processed according to claim 2, the lift mechanism characterized in that
an upper opening of said communication path is opened laterally at the upper-end portion of said pin body.

5. A lift mechanism for an object-to-be-processed according to claim 2, the lift mechanism characterized in that
said collar portion is formed into a shape of an upwardly-convex curved surface.

6. A lift mechanism for an object-to-be-processed according to claim 2, the lift mechanism characterized in that
a notch is formed in said collar portion in order to form a part of said opening.

7. A lift mechanism for an object-to-be-processed according to claim 1, the lift mechanism characterized in that the lower end of said pin body is held in a detachably mounted state on said push-up member.

8. A lift mechanism for an object-to-be-processed according to claim 1, the lift mechanism characterized in that
the lower end of said push-up pin is held in a fixed state on said push-up member.

9. A lift mechanism for an object-to-be-processed according to claim 1, the lift mechanism characterized in that
a lower opening of said communication path is opened laterally at the lower-end portion of said push-up pin.

10. A lift mechanism for an object-to-be-processed including a plurality of pin-insertion holes formed in the mount stand provided inside an evacuatable processing container and a push-up pin inserted through each of said pin-insertion holes, said push-up pin capable of moving upwardly and downwardly, wherein said push-up pin moves upwardly and downwardly so as to mount an object-to-be-processed on said mount stand, the lift mechanism characterized in that:
a communication path is formed in said push-up pin so as to communicate the spaces above and below said mount stand;
a positioning drive pin is formed which is slidably inserted into said communication path of said push-up pin so as to position said push-up pin and to drive said push-up pin upwardly and downwardly; and
a push-up member can move said positioning drive pin upwardly and downwardly.

11. A lift mechanism for an object-to-be-processed according to claim 10, the lift mechanism characterized in that:
said push-up pin has a cylindrical pin body; and
the upper-end portion of said pin body is provided with an annular portion or a collar portion which is held on the peripheral portion of said pin-insertion hole when said push-up pin moves down.

12. A lift mechanism for an object-to-be-processed according to claim 11, the lift mechanism characterized in that
the upper portion of said annular portion or said collar portion is formed into a shape of a convex curved surface.

13. A lift mechanism for an object-to-be-processed according to claim 11, the lift mechanism characterized in that
an upper opening of said communication path is opened upwardly or laterally at the upper end of said pin body.

14. A lift mechanism for an object-to-be-processed according to claim 10, the lift mechanism characterized in that
said positioning drive pin has a projection or collar to engage the lower-end portion of said push-up pin when said positioning drive pin is raised.

15. A lift mechanism for an object-to-be-processed according to claim 10, the lift mechanism characterized in that
said communication path of said push-up pin has a projection, reduced-diameter portion or shoulder portion to engage the upper end of said positioning drive pin when said positioning drive pin is raised.

16. A lift mechanism for an object-to-be-processed according to claim 10, the lift mechanism characterized in that:
the upper-end portion of said positioning drive pin has an evaginated portion;
the lower-end portion of said communication path of said push-up pin has a narrowed portion; and
the length of the maximum outside diameter of said evaginated portion is longer than the length of the minimum inside diameter of said narrowed portion of said communication path.

17. A lift mechanism for an object-to-be-processed according to claim 10, the lift mechanism characterized in that
the lower-end portion of said pin-insertion hole of said mount stand has a projection which engages the lower end of said push-up pin when said push-up pin moves downwardly.

18. A lift mechanism for an object-to-be-processed according to claim 10, the lift mechanism characterized in that
said push-up member slidably holds thereon the lower end of said positioning drive pin.

19. A lift mechanism for an object-to-be-processed according to claim 10, the lift mechanism characterized in that
the lower end of said positioning drive pin is supported in a fixed state by said push-up member.

20. A processing apparatus characterized by comprising:
an evacuatable processing container;
a mount stand to mount an object-to-be-processed;
a lift mechanism for an object-to-be-processed, wherein a plurality of pin-insertion holes are formed in said mount stand,
a push-up pin is inserted through each of said pin-insertion holes, said push-up pin capable of moving upwardly and downwardly,
a push-up member moves said push-up pin upwardly and downwardly so as to mount an object-to-be-processed on said mount stand, and
a communication path is formed in said push-up pin so as to communicate the spaces above and below said mount stand; and
a depressurizer.
